(19) United States
(12) Patent Application Publication
(10) Pub. No.: US 2025/0221015 A1
(43) Pub. Date: Jul. 3, 2025

(54) INTEGRATED DEEP TRENCH HIGH-K CAPACITOR AND METHOD

(71) Applicant: TEXAS INSTRUMENTS INCORPORATED, Dallas, TX (US)

(72) Inventors: Yanbiao Pan, Plano, TX (US); Jackson Bauer, Rowlett, TX (US); Pushpa Mahalingam, Dallas, TX (US); Karl Disher, Lehi, UT (US); Abbas Ali, Plano, TX (US); Ravi Natarajan, Dallas, TX (US)

(21) Appl. No.: 18/397,506

(22) Filed: Dec. 27, 2023

(51) Int. Cl. H01L 27/06; H01L 29/423; H01L 29/51; H01L 29/94

(52) U.S. Cl. CPC H10D 84/811; H10D 1/665; H10D 64/513; H10D 64/514; H10D 64/681

(57) ABSTRACT

Described examples include an integrated circuit including a dielectric layer located over a top surface of a semiconductor substrate and extending over a gate electrode. A trench extends from a top surface of the dielectric layer into the substrate. A conductive trench electrode is within the trench, and a dielectric liner is between the trench electrode and the semiconductor substrate. A cap dielectric layer is located on the conductive trench electrode and on the dielectric layer, and extends over the gate electrode.

### TECHNICAL FIELD

This relates generally to capacitors, and more particularly to capacitors integrated onto integrated circuits.

### BACKGROUND

Integrating capacitors into integrated circuits is a challenge because the capacitance of a capacitor is proportional to the area of the capacitor. However, there is usually not enough available area on an integrated circuit to provide the necessary capacitance. Many techniques have been employed to address this issue, such as folded capacitors, but improving the capacitance per unit area remains a significant challenge.

### SUMMARY

In accordance with an example, an integrated circuit includes a dielectric layer located over a top surface of a semiconductor substrate and extending over a gate electrode. A trench extends from a top surface of the dielectric layer into the substrate. A conductive trench electrode is within the trench, and a dielectric liner is between the trench electrode and the semiconductor substrate. A cap dielectric layer is located on the conductive trench electrode and on the dielectric layer, and extends over the gate electrode.

Another example provides a method of manufacturing an integrated circuit. An electronic device including a gate electrode is formed in or over a semiconductor substrate having a top surface. A protective dielectric layer is deposited over the substrate and the gate electrode, and a trench is formed through the protective dielectric layer and extending into the substrate. A dielectric liner is deposited on a sidewall of the trench, and a conductive material is formed within the trench. A cap dielectric layer is formed that touches a top surface of the conductive material and extends over the gate electrode.

### BRIEF DESCRIPTION OF THE DRAWINGS

FIG. 1 is a side view of an example integrated circuit.

FIG. 2 is a plan view of an example capacitor.

FIGS. 3A-3J (collectively “FIG. 3”) are sideview diagrams illustrating an example process for forming an example capacitor.

### DETAILED DESCRIPTION

In the drawings, corresponding numerals and symbols generally refer to corresponding parts unless otherwise indicated. The drawings are not necessarily drawn to scale.

In this description, the term “coupled” may include connections made with intervening elements, and additional elements and various connections may exist between any elements that are “coupled.” Also, as used herein, the terms “on” and “over” may include layers or other elements where intervening or additional elements are between an element and the element that it is “on” or “over.”

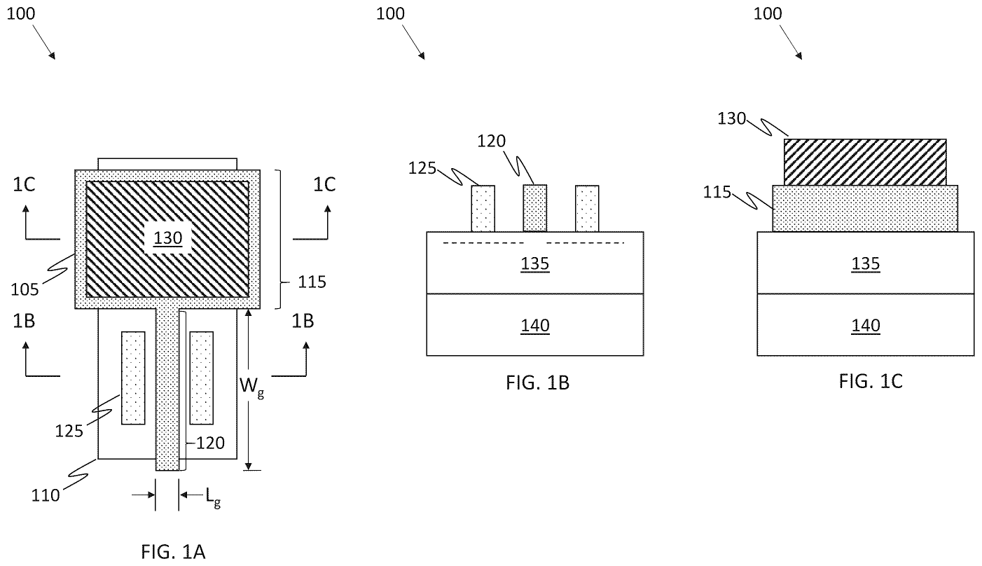

FIG. 1 is a side view of an example integrated circuit 100 with a capacitor 102. Capacitor 102 includes trenches 104 formed in substrate 106 that include dielectric layer 109 and trench electrodes 108. Substrate 106 may be any suitable substrate, for example a semiconductor such as silicon. Substrate 106 may be a doped layer over a bulk substrate such as a portion of a handle wafer. In some examples the substrate 106 is or includes an epitaxially-formed layer, and may be doped n-type or p-type. Trench electrodes 108 include a high conductivity metal such as tungsten, in this example. As further explained below, high-K dielectric layer 109 has a relative dielectric permittivity, colloquially referred to as “K” or “K value” that is greater than that of silicon oxide. The high-K dielectric layer 109 may include a laminate of different dielectric materials, at least one of which is a high-K material. First metal interconnect 110 is connected to trench electrodes 108 by unreferenced contact plugs. First metal interconnect 110, the contact plugs and trench electrodes 108 provide a first terminal of capacitor 102. Substrate 106, second metal contact 112, moat contact 115, and contact layer 113 comprise a second terminal of capacitor 102. Isolation regions 118 in substrate 106 separate the area of capacitor 102 from transistor 114 and transistor 116. In this example, isolation regions 118 are trenches lined with a dielectric, such as silicon dioxide, and filled with a conductor, such as doped polycrystalline silicon. In an alternative example, isolation regions 118 may be formed at that same time as trench electrodes 108, be filled with tungsten, and be isolated with the same dielectric as high-K dielectric layer 109.

Transistor 114 and transistor 116 are example devices. Integrated circuit 100 can include any device that can be formed in a semiconductor device. In this example, gate 120 of transistor 114 is coupled to third metal contact 122 via contact layer 124. Source/drain 126 of transistor 114 is coupled to fourth metal contact 128 via contact layer 130. Source/drain 132 of transistor 114 is coupled to fifth metal contact 134 via contact layer 136. In addition, gate 131 of transistor 116 is coupled to sixth metal contact 140 via contact layer 142. Source/drain 144 of transistor 116 is coupled to seventh metal contact 146 via contact layer 148. Source/drain 150 of transistor 116 is coupled to eighth metal contact 153 via contact layer 154. Optional dielectric layer 107 may be a layer of silicon dioxide and/or silicon nitride that prevents direct contact between the protective layer 105 and electronic components such as the transistors 114 and 116. Pre-metal dielectric (PMD) layer 160 separates the devices in substrate 106 from the first level of metal interconnects. A protective layer 105 completely covers the gates 120, 131, and a dielectric cap layer 111 is located between the PMD layer 160 and the protective layer 105. As explained further hereinbelow, the protective layer 105 may protect electronic devices located over the substrate 106, such as transistor 114 and transistor 116, from processing steps used to form high-K dielectric layer 109, and from contamination by the constituents of the high-K dielectric layer 109.

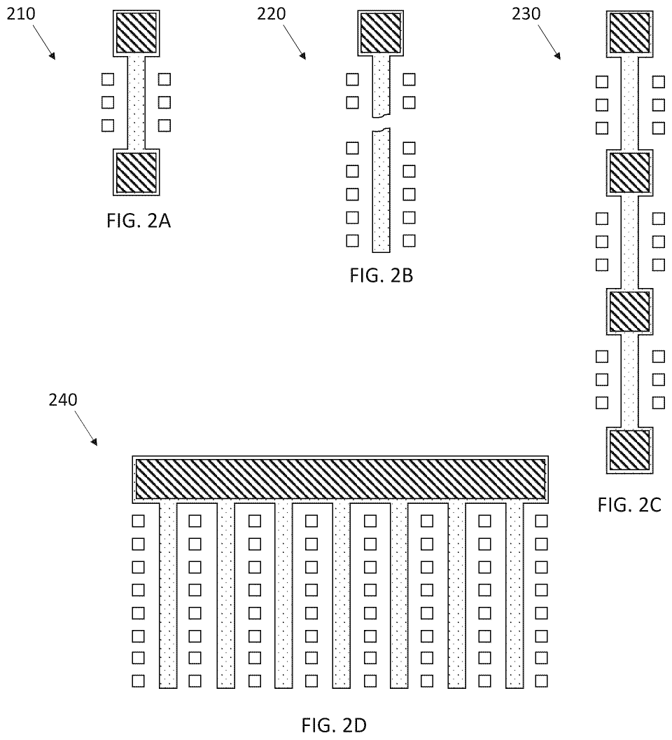

FIG. 2 is a plan view of an example capacitor 102. In FIG. 1, only three trench electrodes 108 are shown. In FIG. 2, twenty-eight trench electrodes 108 are shown. In most examples, a capacitor 102 will include many thousands of trench electrodes 108 to provide the desired capacitance. In the example shown in FIG. 2, each column of trench electrodes 108 shifts vertically relative to the adjacent column, thereby forming a hexagonal array in some examples. This provides increased density of trench electrodes 108 while maintaining as much spacing between trench electrodes 108 as practicable. This is to mitigate the effect of fields from adjacent trench electrodes 108, which may impact the overall capacitance of capacitor 102, and maintains structural integrity of the die (and wafer).

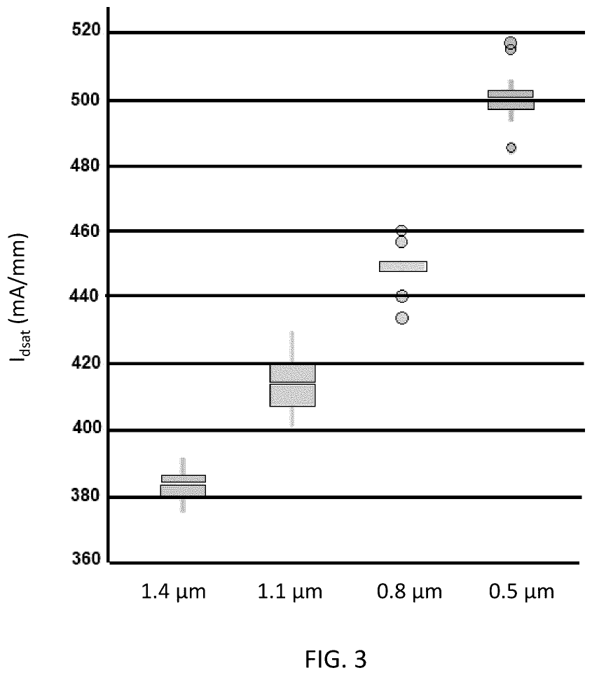

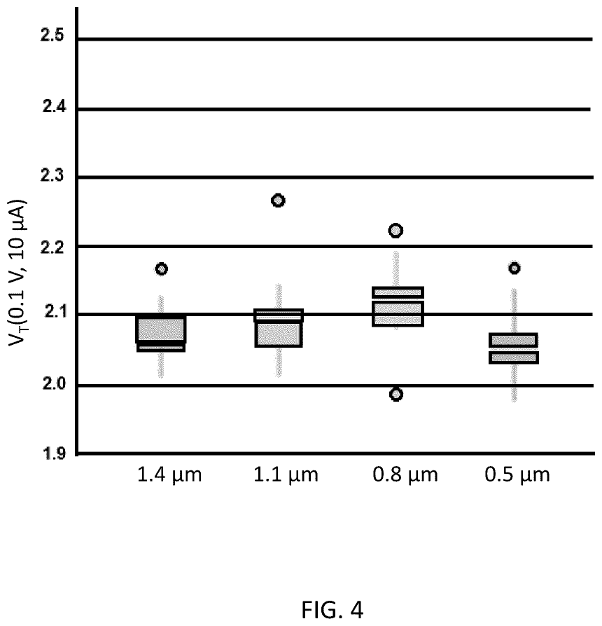

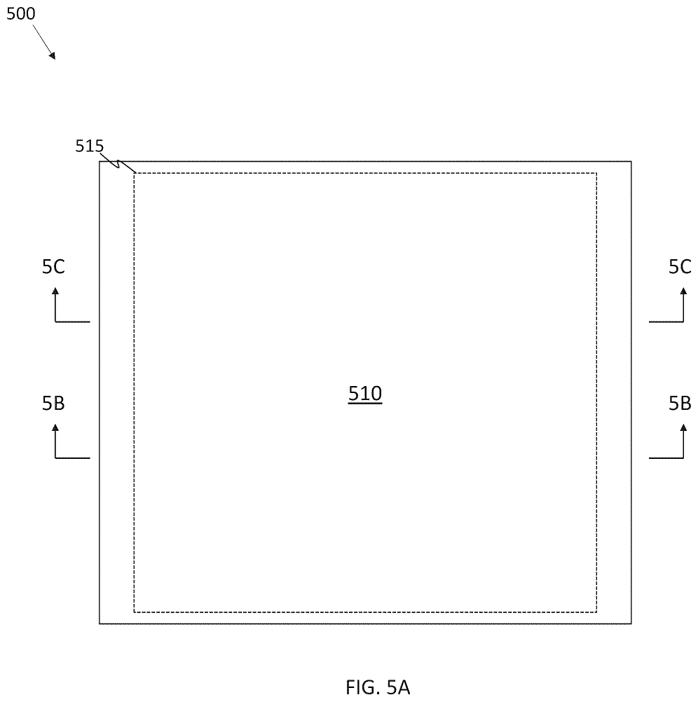

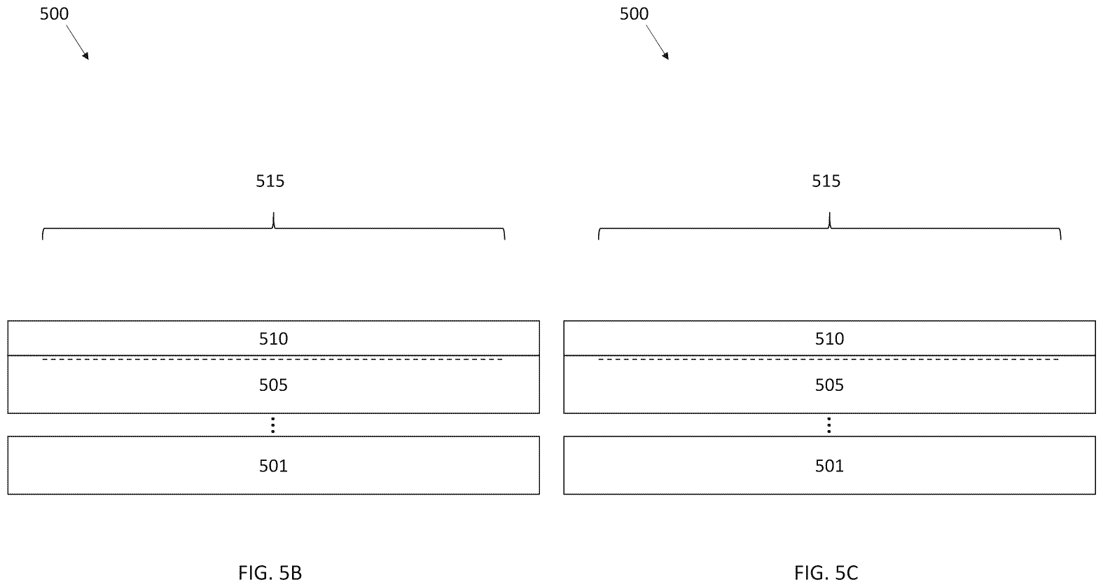

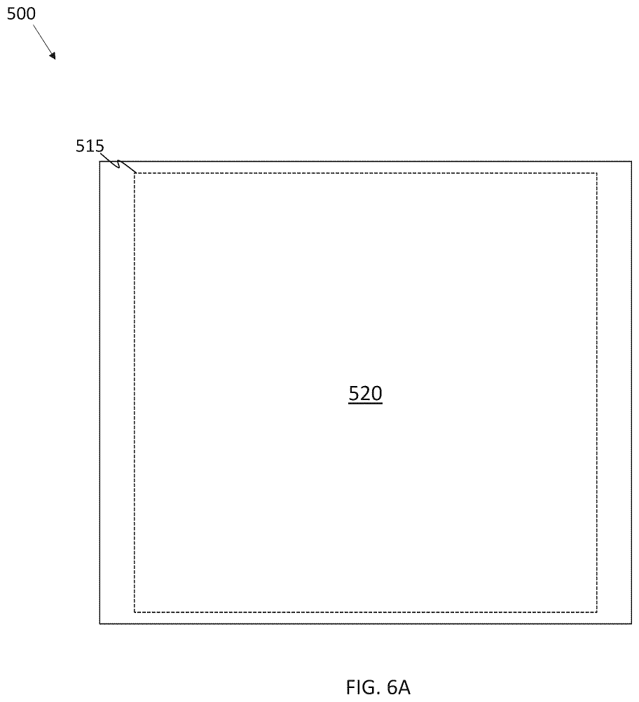

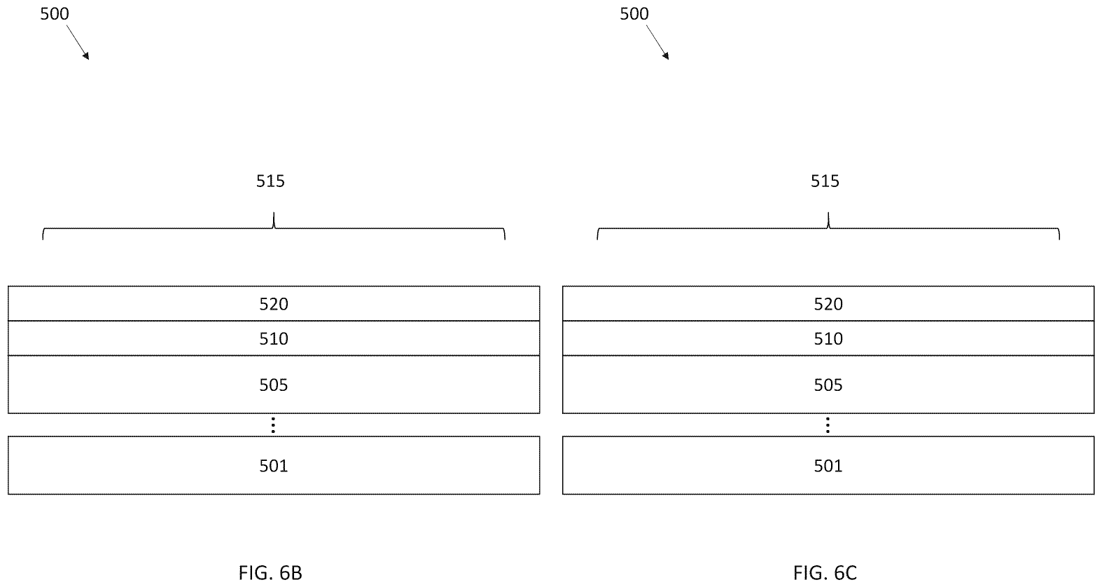

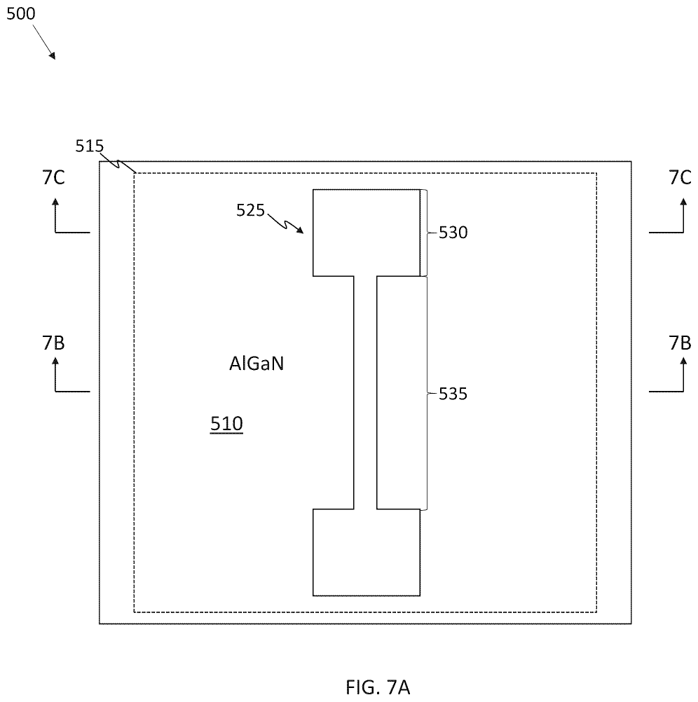

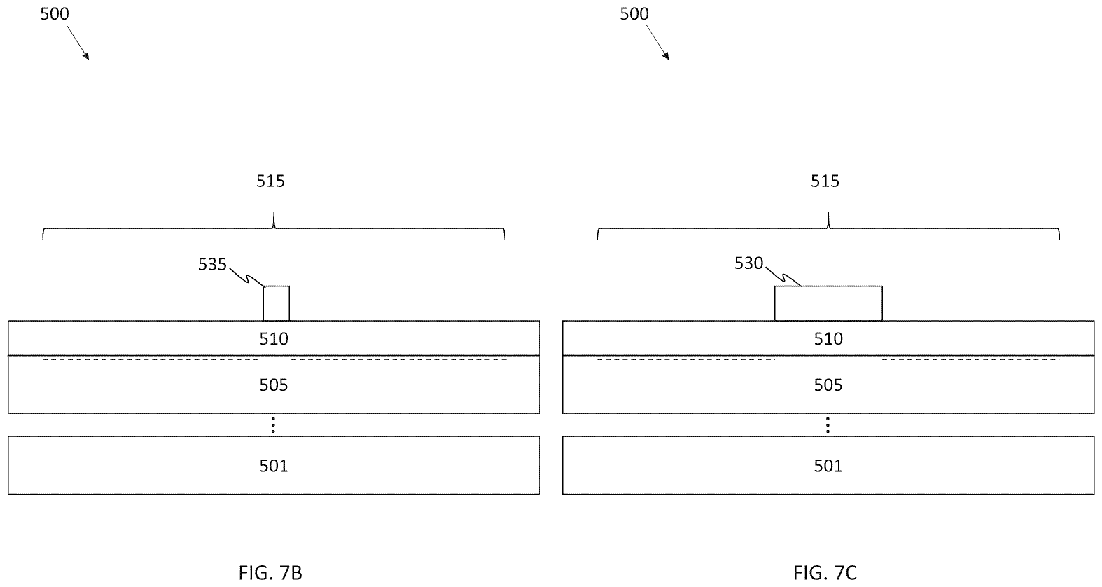

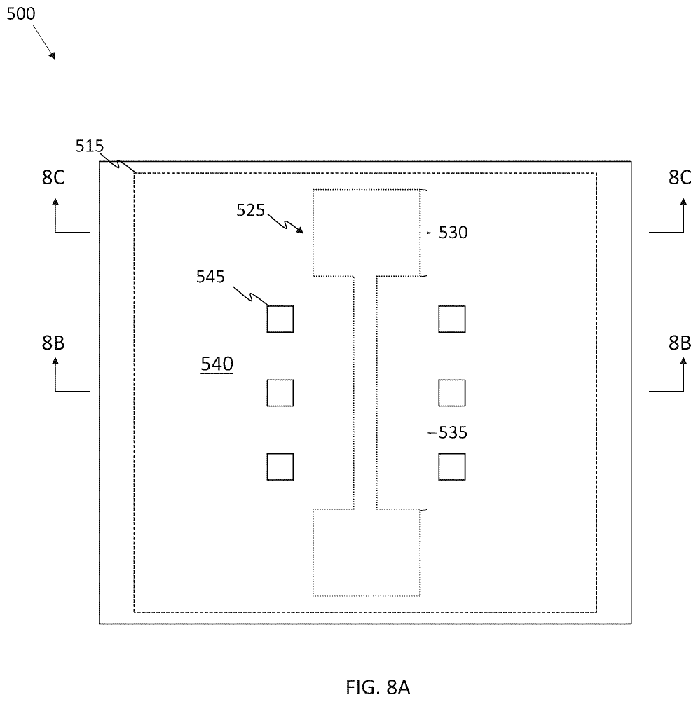

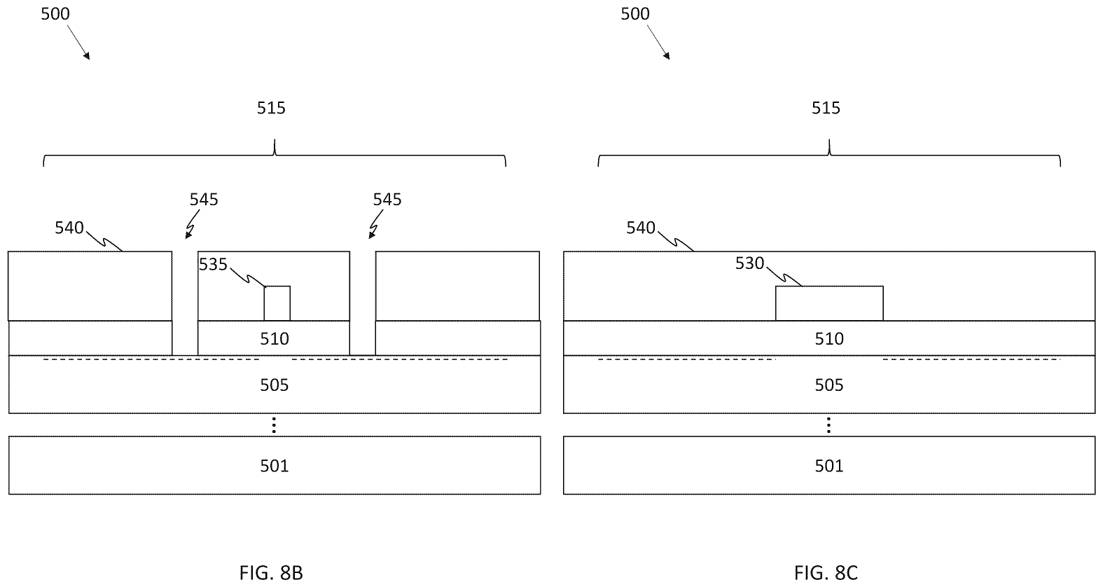

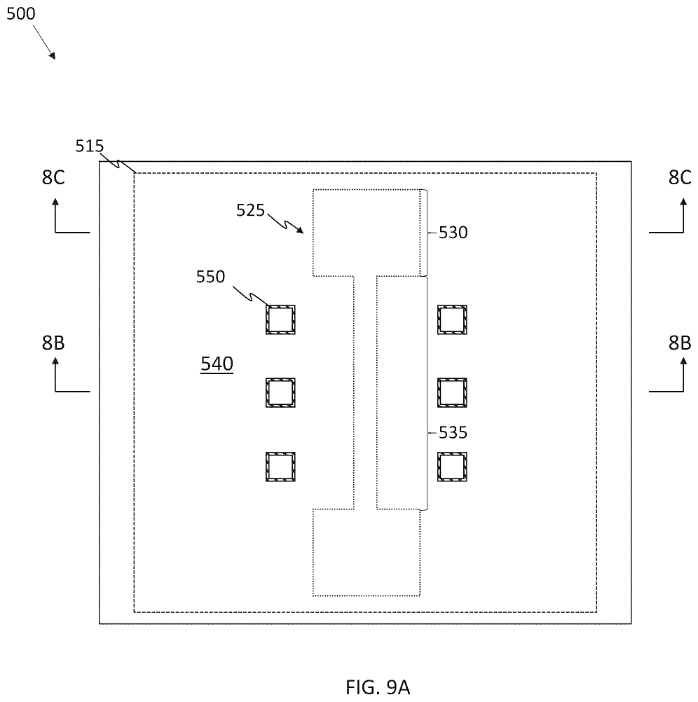

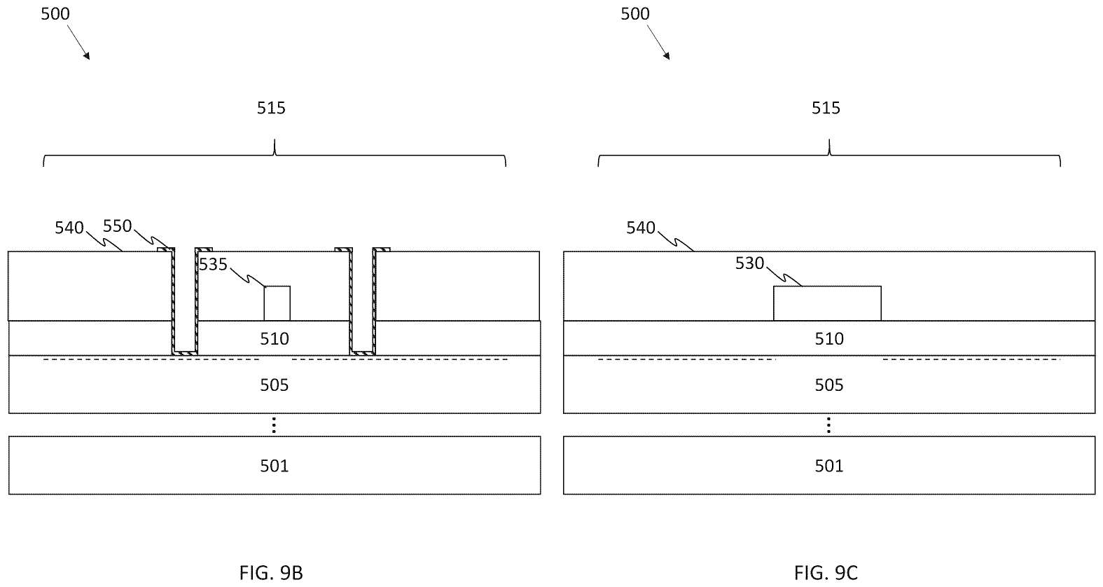

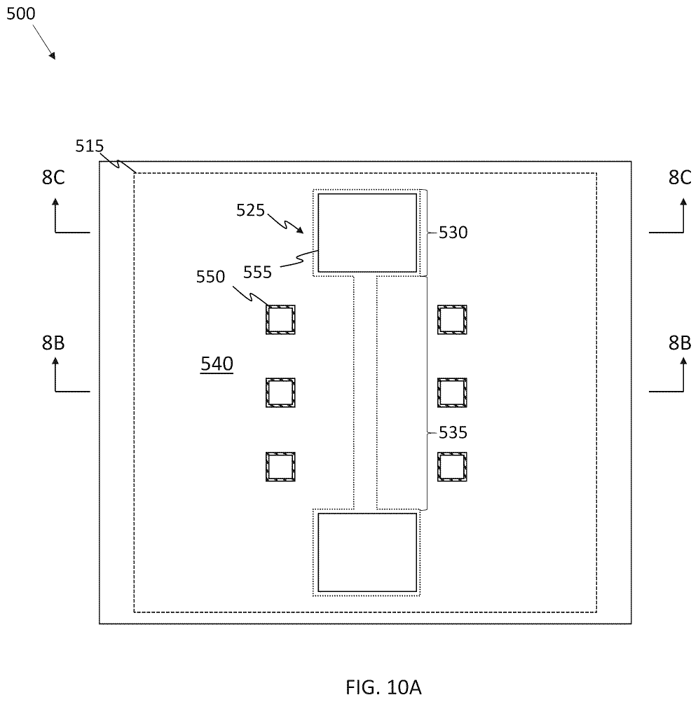

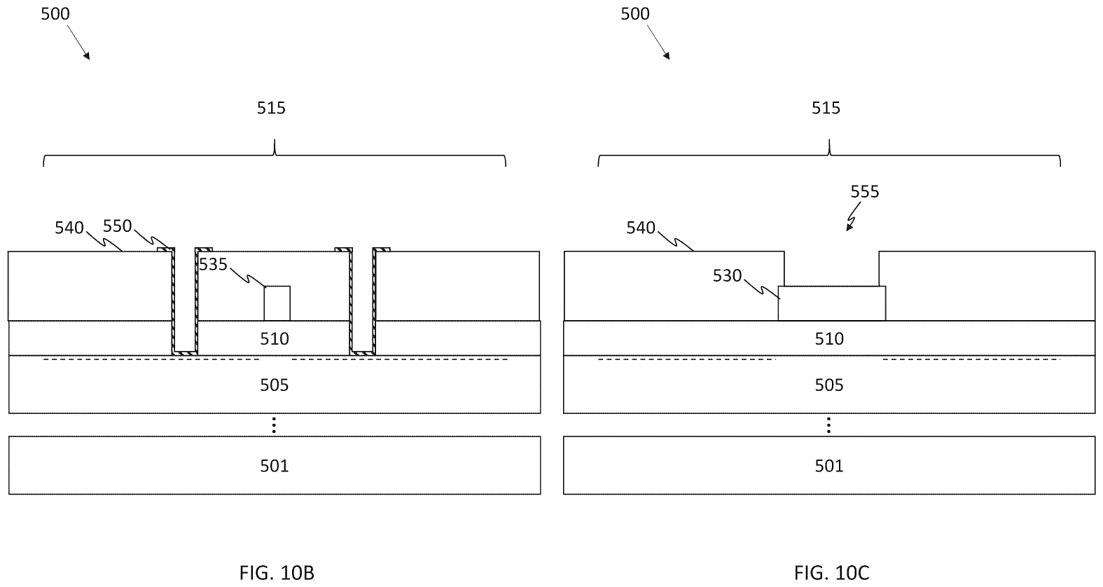

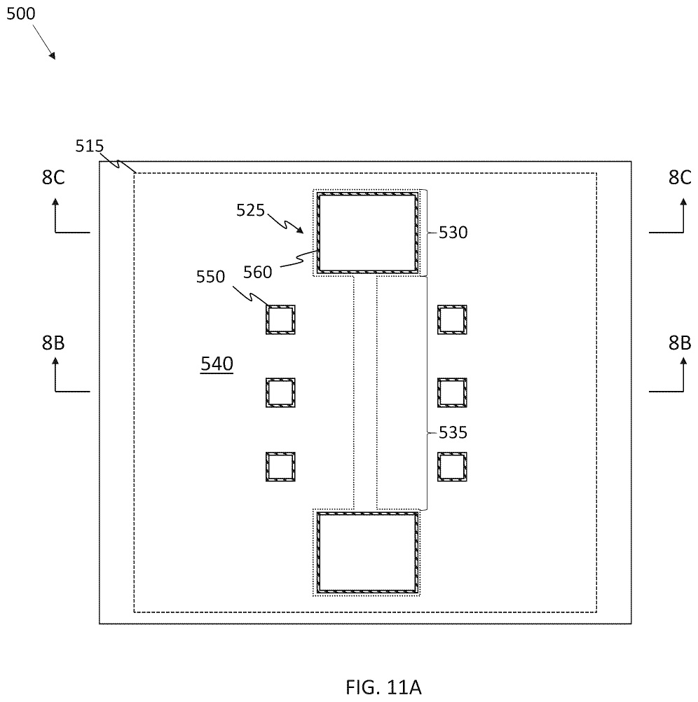

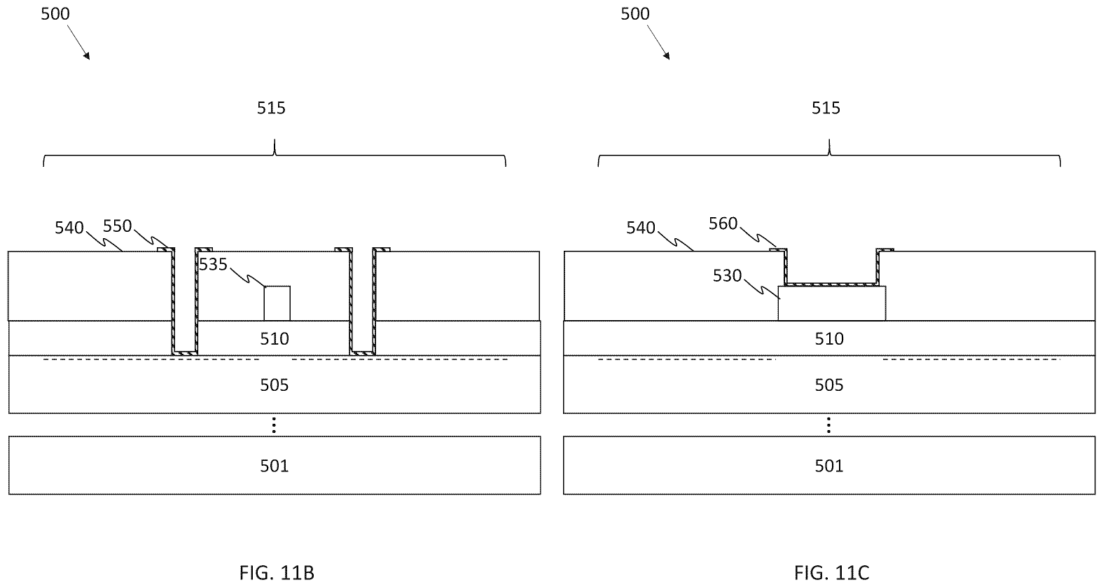

FIGS. 3A-3K (collectively “FIG. 3”) are sideview diagrams illustrating an example process for forming an example capacitor 102. FIG. 3A shows transistor 114, transistor 116 and isolation regions 118 having been previously formed in and over substrate 106 by any known or future-developed processes. The dielectric layer 107 is deposited over the substrate 106 and transistors 114, 116, in some examples using chemical vapor deposition (CVD) of silane in an oxygen ambient to a thickness of 20 nm to 40 nm, for example 35 nm. FIG. 3B shows protective layer 105. CVD forms protective layer 105 on the structure of FIG. 3A. In this example, protective layer 105 is a silicon nitride layer having a thickness of approximately 220 nm with a range between 150 nm and 250 nm thick. Protective layer 105 is then planarized using chemical-mechanical polishing (CMP). In this example, protective layer 105 is patterned and etched using photolithography as shown in FIG. 3B to provide openings to etch trenches 152 using reactive ion etching (RIE) using carbon tetrafluoride, for example. In this example, trenches 152 are approximately 1.2 μm wide and 8 μm deep. These dimensions can vary according to the design requirements and are only limited by available etching and lithographic technology.

FIG. 3C shows an angled implant 155 applied to integrated circuit 100. In this example, angled implant 154 has an angle of 18° and substrate 106 is rotated so that the sidewalls of trenches 152 are uniformly implanted. Angled implant 155 has a density of 5×10¹⁴ to 2×10¹⁵ atoms/cm² and an energy of 150 keV to 300 keV while rotating the wafer 90° four times in this example. An additional vertical implant of 5×10¹⁴ to 1.5×10¹⁵ atoms/cm² and an energy of 25 keV to 75 keV dopes the bottom of trenches 152. This implant has the same conductivity as substrate 106 and increases the conductivity of substrate 106 along the walls of trenches 152, forming a well region (not explicitly shown) around trenches 152 having the same conductivity type as the substrate 106. The well region may provide greater conductivity than the unmodified substrate 106 to implement a portion of the second terminal of the capacitor 102. FIG. 3D shows depositing of high-K dielectric layer 109 as a laminate using atomic layer deposition (ALD). Optionally, a layer of titanium nitride (not shown) is formed by CVD to a thickness of 0.5 nm to 1 nm on the walls of trenches 152 before depositing high-K dielectric layer 109 to improve conductivity of the surfaces of trenches 152 and provide a barrier between high-K dielectric layer 109 and substrate 106.

ALD is a thin-film deposition technique used to create precise, highly conformal, and ultra-thin layers of materials on substrates. ALD, a form of CVD, may deposite one atomic layer at a time, allowing for excellent control over layer thickness and composition. ALD may rely on two chemical precursors that react with an exposed surface one at a time in a sequential, self-limiting, manner. A first precursor may provide elements to be deposited (e.g., a metal or oxide), while a second precursor may be a reactive gas that removes an unwanted portion of the first precursor. In various examples the substrate is exposed to a series of alternating steps. In examples employing two precursors, a deposition process may include steps such as the following to deposit a material layer on a substrate in a process chamber:
Step 1: Introduce the first precursor into the process chamber. The first precursor may chemisorb or react with exposed surfaces of the substrate. The reaction is self-limiting, meaning it stops when all the available sites on the substrate surface are consumed. The temperature of the reaction chamber is 220° C. to 300° C., which is generally lower than other back-end semiconductor fabrication processes.
Step 2: After exposing the substrate surface to the first precursor, any unreacted precursor and byproducts are removed from the chamber to prevent contamination.
Step 3: Introduce the second precursor into the process chamber, reacting with the surface as modified by the first precursor, and saturating any remaining active sites on the substrate.
Step 4: After exposing the substrate surface to the second, any unreacted precursor and byproducts are removed from the chamber to prevent contamination.

The ALD cycle is repeated as many times as needed to achieve the desired film thickness. Over multiple cycles, the controlled, sequential deposition of atomic layers forms the desired thin film. The film thickness is precisely controlled by the number of ALD cycles.

As shown in FIG. 3D, high-K dielectric layer 109 is deposited on substrate 106 so that it covers the walls of trenches 152 and the exposed surface of protective layer 105. As used herein, “high-K” means having a relative dielectric permittivity, colloquially referred to as K, of at least 15. High-K dielectric layer 109 includes alternating layers 156-1, 156-2, 156-3, and 156-4 as shown in the inset, which are alternately zirconium oxide (ZrO₂) and aluminum oxide (Al₂O₃), in this example. The aggregate relative dielectric constant of such a composite dielectric layer may be about 20, for example. Other high-K dielectrics that may be used include hafnium oxide, titanium oxide, tantalum pentoxide, lanthanum oxide, barium oxide, scandium oxide, yttrium oxide, lutetium oxide, and niobium pentoxide. Four layers are shown for simplicity of illustration. Twenty to fifty layers may be effectively employed. In an example, the precursors of ZrO₂ are bis(cyclopentadienyl)dimethylzirconium and ZyALD™ (which is commercially available from Tokyo Electron Limited, Air Liquide and others), along with an oxygenating precursor such as ozone or water vapor. Example precursors of Al₂O₃ are trimethylaluminum, triethylaluminium, aluminum trichloride, and aluminum tri-isopropoxide, along with an oxygenating precursor. This example process is not limited to these chemicals. Many other ALD precursors may be effectively utilized, and new ALD precursor combinations are rapidly being developed. Precursors are also currently commercially available for antimony, arsenic, barium, bismuth, boron, bromine, cadmium, calcium, carbon, cerium, chromium, cobalt, copper, dysprosium, erbium, europium, gadolinium, gallium, germanium, gold, hafnium, holmium, iridium, iron, lanthanum, lead, lithium, lutetium, magnesium, manganese, molybdenum, neodymium, nickel, niobium, osmium, palladium, phosphorus, platinum, praseodymium, rhenium, rhodium, ruthenium, samarium, scandium, selenium, silicon, silver, strontium, tantalum, terbium, thallium, thulium, tin, titanium, tungsten, vanadium, xenon, ytterbium, yttrium, and zinc, thus allowing for a wide range of potential layers. In this example, high-K dielectric layer 109 is a laminate of alternating 5 nm ZrO₂ and 7.5 nm Al₂O₃ layers that are formed until high-K dielectric layer 109 is 20 nm to 50 nm thick. Of importance, protective layer 105 protects the other components in integrated circuit 100, such as transistor 114 and transistor 116, from the precursor chemicals used in the ALD process both during fabrication and after. For example, in the absence of the protective layer 105, constituent elements of the precursors and/or the elements of the high-K layer contaminate other electrical components, thereby affecting device properties such as threshold voltage or breakdown voltage. Notably, the high-K dielectric layer 109 is not limited to ZrO₂ and Al₂O₃. More generally the constituents of the high-K dielectric layer may be selected to meet various electrical design objectives, including capacitance per unit area of the capacitor 102, low DC leakage, and high breakdown voltage. In some examples, it has been determined that a thickness of 25 nm is sufficient to provide a breakdown voltage greater than 20 V. Other applications may apply ALD to providing conforming layers on trenches consistent with other deign objectives.

FIG. 3E shows that a conductive layer 158, which includes a thin layer of titanium nitride (TiN) followed by tungsten (W) deposited by sputtering or CVD, is formed to fill trenches 152. Because transistor 114 and transistor 116 are protected from the materials on high-K dielectric layer 109, a wide range of materials having desirable properties may be employed in high-K dielectric layer 109. An important characteristic is good growth and adhesion for the desired conductor in trenches 152. In this case, the top layer of high-K dielectric layer 109 is Al₂O₃, which has good adhesion to a wide variety of metals. In this example, titanium nitride provides good adhesion and tungsten provides sufficient conductivity to provide low resistance of the trench electrodes 108 even in very deep trenches.

FIG. 3F shows conductive layer after etching using chemical/mechanical polishing (CMP), which removes the portions of conductive layer 158 outside of trenches 152. This leaves trench electrodes 108 in trenches 152. In addition, the portion of high-K dielectric layer 109 outside of trenches 152 is removed by the CMP process. After the CMP process, the cap layer 111, e.g. CVD silicon dioxide, is deposited using CVD, and may have a thickness in a range from 10 nm to 20 nm, for example about 15 nm. The cap layer 111 protects the top surfaces of the trench electrodes 108 during silicide formation at a later stage of processing, thereby effectively acting as a silicide blocking layer. In various examples, and as illustrated, the top surfaces of the trench electrodes are higher than the top surfaces of the gate electrodes 120 and 131 by virtue of the presence of the protective layer 105. The location of a silicide blocking layer vertically spaced apart from the substrate 106 and the gates 120, 131 contrasts with some baseline integration schemes in which a silicide blocking layer is located directly on the top surface of the underlying substrate, possibly with an intervening pad oxide present.

Protective layer 105, the dielectric cap layer 111, and dielectric layer 107 are then patterned as shown in FIG. 3G to provide openings to moat contact 115, source/drain 126, gate 120, source/drain 132, source/drain 144, gate 131, and source/drain 150. FIG. 3H shows a siliciding metal layer 164 sputtered into the openings in the protective layer 105 and contacting moat contact 115, source/drain 126, gate 120, source/drain 132, source/drain 144, gate 131, and source/drain 150. Siliciding metals that are suitable for this example include titanium, molybdenum, cobalt, tungsten and others. The dielectric cap layer 111 protects the trench electrodes 108 from deposition of the siliciding metal layer 164 and later removal of unreacted portions of the siliciding metal layer 164.

FIG. 3I shows the result of annealing integrated circuit 100 with siliciding metal layer 164 in place. The annealing step causes a metal silicide to form where the siliciding metal layer 164 is in contact with the substrate and the polysilicon gates. This annealing step forms contact layer 113, contact layer 130, contact layer 124, contact layer 136, contact layer 148, contact layer 142, and contact layer 154. These contact layers provide an ohmic connection to the underlying silicon elements. The unreacted portion of siliciding metal layer 164 is removed, e.g. by wet etching or another isotropic etching process. The resulting structure is shown in FIG. 3I. In various examples, and as illustrated, the cap layer 111 remains over various portions of the protective layer 105.

PMD layer 160 is then formed on the surface of the structure of FIG. 3J. PMD layer 160 in this example includes silicon oxide formed by CVD deposition using tetraethyl orthosilicate (TEOS), deposited to a thickness of about 1 μm. In some examples the PMD layer 160 may be a phospho-silicate glass (PSG) thus also including phosphorus. It is noted that the material layers in FIG. 3J are not necessarily drawn to scale, so the apparent similarity of thickness of the protective layer 105 and the PMD layer 160 may not reflect examples of manufactured devices. PMD layer 160 is then patterned using photolithography and etching to provide openings to trench electrodes 108, moat contact 115, source/drain 126, gate 120, source/drain 132, source/drain 144, gate 131, and source/drain 150 as shown in FIG. 3J. Unreferenced contact plugs are formed within the PMD layer to the trench electrodes 108 and various silicided electrical contacts. In various examples, the contact plugs are formed by tungsten CVD after a thin layer of titanium nitride.

After forming the contact plugs, processing may continue by any conventional or future-developed techniques to form interconnect metallization and dielectric layers over the substrate 106, as represented by FIG. 1. Such interconnects may include copper and/or aluminum metallization schemes, and may connect the first and second terminals of the capacitor 102 to other components of the integrated circuit 100. The total thickness of the protective layer 105 and the cap layer 111 may be consistent with otherwise baseline integrated circuits, such that the extension of the trench electrodes 108 above the top surface of the substrate 106 does not affect later interconnect processing.

Notably, because trenches 152, and thus high-K dielectric layer 109, are formed after the protective layer 105, contamination of other parts of the integrated circuit 100 with the materials used in the fabrication of high-K dielectric layer 109 that could otherwise occur is limited or prevented, both during the formation of high-K dielectric layer 109 and afterward in the completed device. Enabling the use of ALD for forming high-K dielectric layer 109 provides not only the advantage of increasing the capacitance per unit area of capacitor 102, the highly conformal nature of ALD enables using very deep trenches, which also enhances the capacitance per unit area. In addition, ALD allows for the selection of a high-K dielectric that has good adhesion to deposited metal, such as tungsten, which is more conductive than doped polysilicon, thus mitigating resistance effects with respect to the capacitance in the lower portions of the trench. In various examples these aspects may provide significantly greater capacitance per unit area relative to analogous baseline capacitors using thermal silicon dioxide as the trench liner. For example, in some experimental devices having a ZrO₂/Al₂O₃ composite dielectric capacitor dielectric, a capacitance of 54 fF/μm² has been demonstrated, which is approximately 3 times greater than baseline deep trench capacitors and 40 times some planar capacitors.

Modifications are possible in the described examples, and other examples are possible, within the scope of the claims.

What is claimed is:

1. An integrated circuit comprising:
a semiconductor substrate having a first top surface;
a first dielectric layer located over the first top surface and having a second top surface;
a trench extending from the second top surface through the first dielectric layer and into the substrate;
a conductive trench electrode within the trench; and
a dielectric liner between the trench electrode and the semiconductor substrate.

2. The integrated circuit of claim 1, wherein the dielectric liner includes a high-K dielectric.

3. The integrated circuit of claim 2, wherein the high-K dielectric is selected from the group consisting of zirconium oxide, hafnium oxide, aluminum oxide, hafnium oxide, titanium oxide, tantalum pentoxide, lanthanum oxide, barium oxide, scandium oxide, yttrium oxide, lutetium oxide, and niobium pentoxide.

4. The integrated circuit of claim 1, wherein the first dielectric layer covers a transistor gate electrode.

5. The integrated circuit of claim 4, wherein a top surface of the gate electrode extends above the top surface of the substrate by a first distance, and a top surface of the trench electrode extends above the substrate top surface by a second greater distance.

6. The integrated circuit of claim 1, wherein a second dielectric layer extends between the second top surface and an interconnect layer.

7. The integrated circuit of claim 1, wherein the dielectric liner is at least 200 nm thick.

8. The integrated circuit of claim 1, further comprising a first contact plug having a first length from the trench electrode to an interconnect metallization layer, and a second contact plug having a greater second length from the substrate top surface to the interconnect metallization layer.

9. The integrated circuit of claim 1, wherein the conductive trench electrode is one of an array of conductive trenches forming a trench capacitor having a capacitance density of at least 50 fF/μm².

10. The integrated circuit of claim 1, wherein the dielectric liner includes alternating layers of different dielectric materials.

11. A process comprising:
forming an electronic device in or over a semiconductor substrate having a top surface, the electronic device including a gate electrode;
depositing a protective dielectric layer over the substrate and the gate electrode;
forming a trench through the protective dielectric layer and extending into the substrate;
depositing a dielectric liner on a sidewall of the trench;
forming a conductive material within the trench; and
forming a cap dielectric layer that touches a top surface of the conductive material and extends over the gate electrode.

12. The process of claim 11, wherein the dielectric liner has a dielectric constant of at least 15.

13. The process of claim 11, further comprising:
forming a pre-metal dielectric (PMD) layer over the protective dielectric layer;
forming a first contact plug that extends through the PMD layer to the conductive material; and
forming a second contact plug that extends through the PMD layer to the top surface.

14. The process of claim 13, wherein the conductive material and the first and second contact plugs comprise tungsten.

15. The process of claim 11, wherein the dielectric liner is deposited using atomic layer deposition.

16. The process of claim 11, wherein the dielectric liner includes alternating layers of different dielectric materials.

17. The process of claim 16, wherein the dielectric liner includes alternating layers of zirconium oxide and aluminum oxide.

18. The process of claim 11, further comprising forming a cap dielectric layer on a top surface of the conductive material, and forming a pre-metal dielectric (PMD) layer on the cap dielectric layer.

19. The process of claim 11, wherein trench is one of an array of trenches of a trench capacitor having a capacitance density of at least 50 fF/μm^{2.}

20. The process of claim 11, wherein the dielectric liner includes a material selected from the group consisting of zirconium oxide, hafnium oxide, aluminum oxide, hafnium oxide, titanium oxide, tantalum pentoxide, lanthanum oxide, barium oxide, scandium oxide, yttrium oxide, lutetium oxide, and niobium pentoxide.
